(19) United States
(12) Patent Application Publication
(10) Pub. No.: US 2026/0107617 A1
(43) Pub. Date: Apr. 16, 2026

(54) DISPLAY DEVICE AND ELECTRONIC DEVICE INCLUDING THE SAME

(71) Applicant: Samsung Display Co., LTD., Yongin-si (KR)

(72) Inventors: Gwang Min CHA, Yongin-si (KR); Jun Gi KIM, Yongin-si (KR); Youn Joo RYU, Yongin-si (KR); Sang Hyun YUN, Yongin-si (KR); Jae Hun LEE, Yongin-si (KR)

(21) Appl. No.: 19/213,152

(22) Filed: May 20, 2025

(30) Foreign Application Priority Data
Oct. 15, 2024 (KR) 10-2024-0140594

(51) Int. Cl. H10H 29/855; H10H 29/37

(52) U.S. Cl. CPC H10H 29/855; H10H 29/37

(57) ABSTRACT

A display device includes: a substrate including a first sub-pixel and a second sub-pixel having a viewing angle narrower than a viewing angle of the first sub-pixel, a display layer on the substrate, a transmission layer on the display layer, a first light blocking layer disposed in the transmission layer and between the first sub-pixel and the second sub-pixel in a plan view, a second light blocking layer disposed in the transmission layer and overlapping with the second sub-pixel in the plan view, and a lens on a side surface of the first light blocking layer.

The present application claims priority to Korean patent application No. 10-2024-0140594 filed on Oct. 15, 2024, and all the benefits accruing therefrom under 35 U.S. C. § 119, the content of which in its entirety is herein incorporated by reference.

### BACKGROUND

### 1. Technical Field

The present disclosure generally relates to a display device and an electronic device.

### 2. Related Art

Recently, as interest in information displays is increased, research and development of display devices have been continuously conducted.

### SUMMARY

Embodiments provide a display device in which a viewing angle of the display device can be easily controlled and front light output efficiency (i.e., light output efficiency to a front surface of a display device) can be effectively improved.

In accordance with an aspect of the present disclosure, there is provided a display device including: a substrate including a first sub-pixel and a second sub-pixel having a viewing angle narrower than a viewing angle of the first sub-pixel; a display layer on the substrate; a transmission layer on the display layer; a first light blocking layer disposed in the transmission layer and between the first sub-pixel and the second sub-pixel in a plan view; a second light blocking layer disposed in the transmission layer and overlapping with the second sub-pixel in the plan view; and a lens on a side surface of the first light blocking layer.

The first light blocking layer and the second light blocking layer may extend along a first direction in the plan view.

The first light blocking layer and the second light blocking layer may be spaced apart from each other along a second direction intersecting the first direction.

The lens may extend along the first direction in the plan view.

The lens may be disposed between the first sub-pixel and the first light blocking layer in the plan view.

The first sub-pixel and the second sub-pixel may emit lights of different colors from each other.

The first light blocking layer may include a first side surface adjacent to the first sub-pixel and a second side surface adjacent to the second sub-pixel and opposite to the first side surface. The lens may be disposed on the first side surface, not on the second side surface.

The lens may be in contact with the first side surface.

The display layer may include: a first electrode; a pixel defining layer defining an opening therein exposing the first electrode; a light emitting layer on the first electrode and in the opening; and a second electrode on the light emitting layer.

The lens may overlap with the pixel defining layer in the plan view.

The lens may not overlap with the light emitting layer in the plan view.

The first light blocking layer may overlap with the pixel defining layer in the plan view.

The first light blocking layer may not overlap with the light emitting layer of the first sub-pixel in the plan view.

The second light blocking layer may overlap with the light emitting layer of the second sub-pixel in the plan view.

A refractive index of the transmission layer may be greater than a refractive index of the lens.

In accordance with another aspect of the present disclosure, there is provided a display device including: a substrate including a first pixel and a second pixel having a viewing angle narrower than a viewing angle of the first pixel; a display layer on the substrate; light blocking layers overlapping with the second pixel on the display layer in a plan view; a lens disposed between the light blocking layers; and a transmission layer disposed between the light blocking layer and the lens.

The light blocking layers may not overlap with the first pixel in the plan view.

The second pixel may include a first sub-pixel and a second sub-pixel, which emit lights of different colors from each other. The lens may be disposed between the first sub-pixel and the second sub-pixel.

The transmission layer may surround an entirety of the lens.

A refractive index of the transmission layer may be greater than a refractive index of the lens.

In accordance with an aspect of the present disclosure, there is provided an electronic device including: a processor to provide input image data; and a display device to display an image based on the input image data, where the display device includes: a substrate including a first sub-pixel and a second sub-pixel having a viewing angle narrower than a viewing angle of the first sub-pixel; a display layer on the substrate; a transmission layer on the display layer; a first light blocking layer disposed in the transmission layer and between the first sub-pixel and the second sub-pixel in a plan view; a second light blocking layer disposed in the transmission layer and overlapping with the second sub-pixel in the plan view; and a lens on a side surface of the first light blocking layer.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating an embodiment of a display device.

FIG. 2 is a block diagram illustrating an embodiment of a sub-pixel.

FIG. 3 is a circuit diagram illustrating an embodiment of the sub-pixel.

FIG. 4 is a plan view illustrating an embodiment of a display panel shown in FIG. 1.

FIG. 5 is a plan view illustrating an embodiment of a pixel shown in FIG. 4.

FIGS. 6 and 7 are sectional views taken along line A-A′ shown in FIG. 5.

FIG. 8 is a plan view illustrating another embodiment of the pixel shown in FIG. 4.

FIGS. 9 and 10 are sectional views taken along line B-B′ shown in FIG. 8.

FIG. 11 is a perspective view illustrating an application example of the display device.

FIGS. 12 to 17 are sectional views illustrating process steps of a method of manufacturing a display device in accordance with an embodiment of the present disclosure.

FIGS. 18 to 23 are sectional views illustrating process steps of a method of manufacturing a display device in accordance with an embodiment of the present disclosure.

FIG. 24 is a block diagram of an electronic device according to an embodiment.

FIG. 25 shows schematic views of various embodiments of an electronic device.

### DETAILED DESCRIPTION

Hereinafter, embodiments of the present disclosure will be described in more detail with reference to the accompanying drawings. In the description below, only a necessary part to understand an operation according to the present disclosure is described and the descriptions of other parts are omitted in order not to unnecessarily obscure subject matters of the present disclosure. In addition, the present disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the present disclosure, so that changes in a shape as shown due to, for example, manufacturing technology and/or a tolerance may be expected. Therefore, the embodiments of the present disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

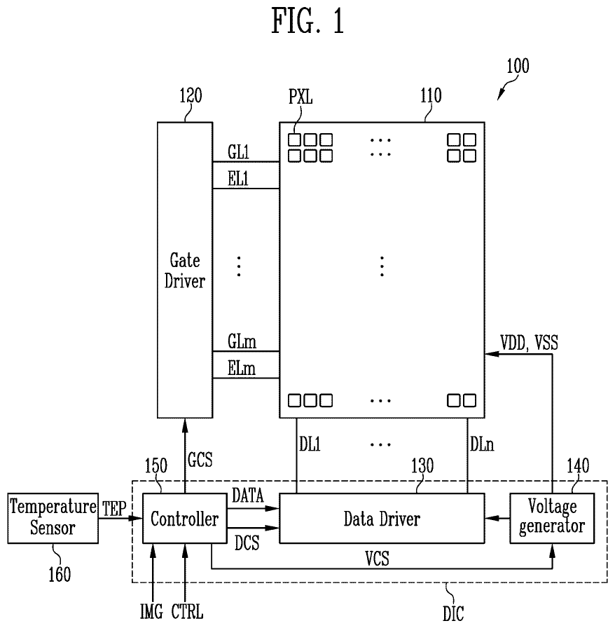

FIG. 1 is a block diagram illustrating an embodiment of a display device.

Referring to FIG. 1, the display device 100 may include a display panel 110, a gate driver 120, a data driver 130, a voltage generator 140, and a controller 150. The display device 100 may be applied to electronic devices such as a smart phone, a computing system, a display system, smart glasses, an HMD, and a vehicle display device.

The display panel 110 may include pixels PXL. The pixels PXL may be connected to the gate driver 120 through first to mth gate lines GL1 to GLm. The pixels PXL may be connected to the data driver 130 through first to nth data lines DL1 to DLn.

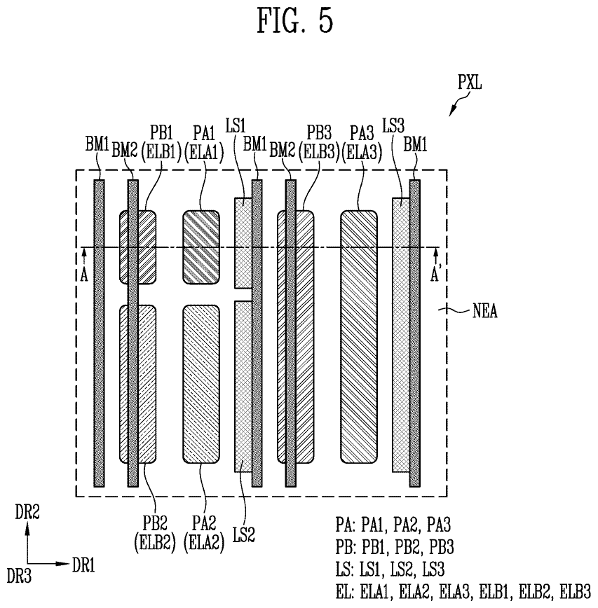

Each pixel PXL may be configured with a plurality of sub-pixels. Each of the sub-pixels may include at least one light emitting element configured to generate light. Accordingly, each of the sub-pixels may generate light of a specific color such as red, green, blue, cyan, magenta or yellow. In an embodiment, the display panel 110 may be a switchable privacy display panel in which a switch between a normal mode (or first mode) and a privacy mode (or second mode) in which a viewing angle is limited is possible. As such, when the display panel 110 supports the privacy mode, the pixel PXL may include first pixels (or normal pixels) emitting light in the normal mode and second pixels (or privacy pixels) emitting light in the privacy mode. This will be described in detail later with reference to FIG. 5 and the like.

The gate driver 120 may be connected to the sub-pixels arranged in a row direction through the first to mth gate lines GL1 to GLm. The gate driver 120 may output gate signals to the first to mth gate lines GL1 to GLm in response to a gate control signal GCS. In an embodiment, the gate control signal GCS may include a start signal indicating a start of each frame, a horizontal synchronization signal for outputting gate signals in synchronization with timings at which data signals are applied, and the like.

In an embodiment, first to mth emission control lines EL1 to ELm connected to the sub-pixels in the row direction may be further provided. The gate driver 120 may include an emission control driver configured to control the first to mth emission control lines EL1 to ELm, and the emission control driver may operate under the control of the controller 150.

The gate driver 120 may be disposed at one side of the display panel 110. However, embodiments are not limited thereto. For example, the gate driver 120 may be divided into two or more drivers which are physically and/or logically divided, and these drivers may be disposed at one side of the display panel 110 and the other side of the display panel 110, which is opposite to the one side. As such, in accordance with embodiments, the gate driver 120 may be disposed in various forms at the periphery of the display panel 110.

The data driver 130 may be connected to the sub-pixels arranged in a column direction through the first to nth data lines DL1 to DLn. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, and the like.

The data driver 130 may apply data signals having grayscale voltages corresponding to the image data DATA to the first to nth data lines DL1 to DLn by using voltages from the voltage generator 140. When a gate signal is applied to each of the first to mth gate lines GL1 to GLm, data signals corresponding to the image data DATA may be applied to the data lines DL1 to DLn. Accordingly, corresponding sub-pixels may generate light corresponding to the data signals. Accordingly, an image may be displayed on the display panel 110.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device 100. For example, the voltage generator 140 may be configured to generate a plurality of voltages by receiving an input voltage from an outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels. The first power voltage VDD may have a relatively high voltage level, and the second power voltage VSS may have a voltage level lower than the voltage level of the first power voltage VDD. In another embodiment, the first power voltage VDD or the second power voltage VSS may be provided by an external device of the display device 100.

Besides, the voltage generator 140 may generate various voltages. For example, the voltage generator 140 may generate an initialization voltage applied to the sub-pixels. For example, a predetermined reference voltage may be applied to the first to nth data lines DL1 to DLn in a sensing operation for sensing electrical characteristics of transistors and/or light emitting elements of the sub-pixels, and the voltage generator 140 may generate the reference voltage.

The controller 150 may control overall operations of the display device 100. The controller 150 may receive, from the outside, input image data IMG and a control signal CTRL for controlling display thereof. The controller 150 may provide the gate control signal GCS, the data control signal DCS, and the voltage control signal VCS in response to the control signal CTRL.

The controller 150 may convert the input image data IMG to be suitable for the display device 100 or the display panel 110, thereby outputting the image data DATA. In an embodiment, the controller 150 may align the input image data IMG to be suitable for the sub-pixels in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In another embodiment, at least one of the data driver 130, the voltage generator 140, and the controller 150 may be provided as a component distinguished from the driver integrated circuit DIC.

The display device 100 may include at least one temperature sensor 160. The temperature sensor 160 may be configured to sense a temperature at the periphery thereof and generate temperature data TEP indicating the sensed temperature. In an embodiment, the temperature sensor 160 may be disposed to be adjacent to the display panel 110 and/or the driver integrated circuit DIC.

The controller 150 may control various operations of the display device 100 in response to the temperature data TEP. In an embodiment, the controller 150 may adjust the luminance of an image output from the display panel 110 in response to the temperature data TEP. For example, the controller 150 may control components such as the data driver 130 and/or the voltage generator 140, thereby adjusting data signals and the first and second power voltages VDD and VSS.

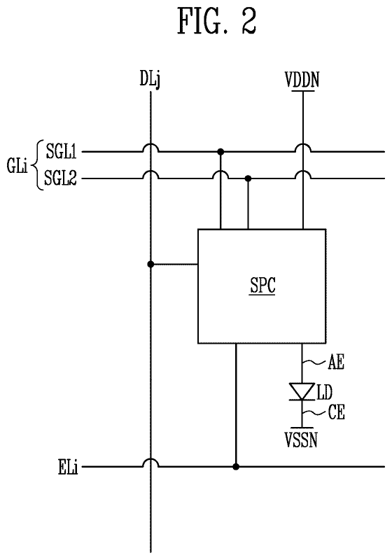

FIG. 2 is a block diagram illustrating an embodiment of a sub-pixel.

In FIG. 2, a sub-pixel arranged on an ith row (i is an integer greater than or equal to 1 and smaller than or equal to m) and a jth column (j is an integer greater than or equal to 1 and smaller than or equal to n) is exemplarily illustrated.

Referring to FIG. 2, the sub-pixel may include a pixel circuit SPC and a light emitting element LD. The light emitting element LD may be connected between a first power voltage node VDDN and a second power voltage node VSSN. The first power voltage node VDDN may be a node which the first power voltage VDD shown in FIG. 1 is transferred, and the second power voltage node VDDN may be a node through which the second power voltage VSS shown in FIG. 1 is transferred.

An anode electrode AE of the light emitting element LD may be connected to the first power voltage node VDDN through the pixel circuit SPC, and a cathode electrode AE of the light emitting element LD may be connected to the second power voltage node VSSN. For example, the anode electrode AE of the light emitting element LD may be connected to the first power voltage node VDDN through one or more transistors included in the pixel circuit SPC.

The pixel circuit SPC may be connected to an ith gate line GLi among the first to mth gate lines GL1 to GLm shown in FIG. 1, an ith emission control line ELi among the first to mth emission control lines EL1 to ELm shown in FIG. 1, and a jth data line DLj among the first to nth data lines DL1 to DLn shown in FIG. 1. The pixel circuit SPC may be configured to control the light emitting element LD according to signals received through these signal lines.

The pixel circuit SPC may operate in response to a gate signal received through the ith gate line GLi. The ith gate line GLi may include one or more sub-gate lines. In an embodiment, as shown in FIG. 2, the ith gate line GLi may include first and second sub-gate lines SGL1 and SGL2. The pixel circuit SPC may operate in response to gate signals received through the first and second sub-gate lines SGL1 and SGL2. As such, when the ith gate line GLi includes two or more sub-gate lines, the pixel circuit SPC may operate in response to gate signals received through the corresponding sub-gate lines.

The pixel circuit SPC may operate in response to an emission control signal received through the ith emission control line ELi. In an embodiment, the ith emission control line ELi may include one or more sub-emission control lines. When the ith emission control line ELi includes two or more sub-emission control lines, the pixel circuit SPC may operate in response to emission control signals received through the corresponding sub-emission control lines.

The pixel circuit SPC may receive a data signal through the jth data line DLj. The pixel circuit SPC may store a voltage corresponding to the data signal in response to at least one of the gate signals received through the first and second sub-gate lines SGL1 and SGL2. The pixel circuit SPC may adjust a current flowing from the first power voltage node VDDN to the second power voltage node VSSN through the light emitting element LD according to the stored voltage in response to the emission control signal received through the ith emission control line ELi. Accordingly, the light emitting element LD may generate light with a luminance corresponding to the data signal.

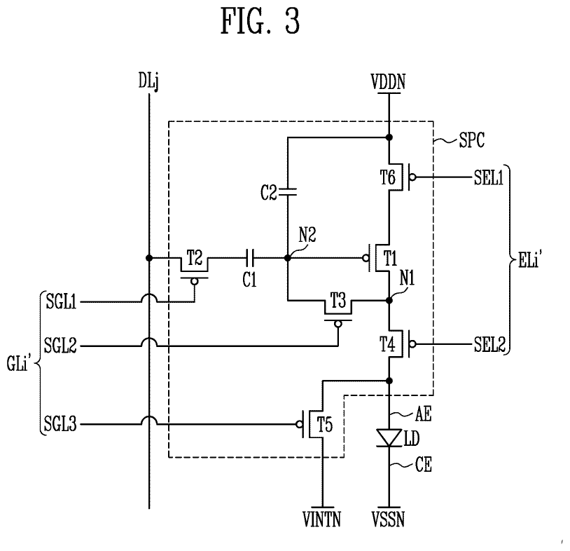

FIG. 3 is a circuit diagram illustrating an embodiment of the sub-pixel.

Referring to FIG. 3, a sub-pixel may include a pixel circuit SPC and a light emitting element LD.

The pixel circuit SPC may be connected to an ith gate line GLi′, an ith emission control line ELi′, and a jth data line DLj. When comparing the ith gate line GLi′ with the ith gate line GLi shown in FIG. 2, the ith gate line GLi′ may further include a third sub-gate line SGL3. When comparing the ith emission control line ELi′ with the ith emission control line ELi shown in FIG. 2, the ith emission control line ELi′ may include a first sub-emission control line SEL1 and a second sub-emission control line SEL2.

The pixel circuit SPC may include first to sixth transistors T1 to T6 and first and second capacitors C1 and C2.

The first transistor T1 may be connected between a first power voltage node VDDN and a first node N1. A gate of the first transistor T1 may be connected to a second node N2, and accordingly, the first transistor T1 may be turned on according to a voltage level of the second node N2. The first transistor T1 may be designated as a driving transistor.

The second transistor T2 may be connected between the jth data line DLj and the second node N2. A gate of the second transistor T2 may be connected to a first sub-gate line SGL1, and accordingly, the second transistor T2 may be turned on in response to a gate signal of the first sub-gate line SGL1. The second transistor T2 may be designated as a switching transistor.

The third transistor T3 may be connected between the first node N1 and the second node N2. A gate of the third transistor T3 may be connected to a second sub-gate line SGL2, and accordingly, the third transistor T3 may be turned on in response to a gate signal of the second sub-gate line SGL2.

The fourth transistor T4 may be connected between the first node N1 and an anode electrode AE of the light emitting element LD. A gate of the fourth transistor T4 may be connected to the second sub-emission control line SEL2, and accordingly, the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transfer an initialization voltage. In an embodiment, the initialization voltage may be provided by the voltage generator 140 shown in FIG. 1. In another embodiment, the initialization voltage may be provided by an external device of the display device 100. A gate of the fifth transistor T5 may be connected to the third sub-gate line SGL3, and accordingly, the fifth transistor T5 may be turned on in response to a gate signal of the third sub-gate line SGL3.

The sixth transistor T6 may be connected between the first power voltage node VDDN and the first transistor T1. A gate of the sixth transistor T6 may be connected to the first sub-emission control line SEL1, and accordingly, the sixth transistor T6 may be turned on in response to an emission control signal of the first sub-emission control line SEL1.

The first capacitor C1 may be connected between the second transistor T2 and the second node N2. The second capacitor C2 may be connected between the first power voltage node VDDN and the second node N2.

As such, the pixel circuit SPC may include the first to sixth transistors T1 to T6 and the first and second capacitors C1 and C2. However, embodiments are not limited thereto. The pixel circuit SPC may be implemented as any one of various types of circuits each including a plurality of transistors and one or more capacitors. For example, the pixel circuit SPC may include two transistors and one capacitor. In accordance with embodiments of the pixel circuit SPC, the number of sub-gate lines included in the ith gate line GLi′ and the number of sub-emission control lines included in the ith emission control line ELi′ may vary.

The first to sixth transistors T1 to T6 may be P-type transistors. Each of the first to sixth transistors T1 to T6 may be a Metal Oxide Silicon Field Effect Transistor (MOSEFT). However, embodiments are not limited thereto. For example, at least one of the first to sixth transistors T1 to T6 may be replaced with an N-type transistor.

In an embodiment, the first to sixth transistors T1 to T6 may include an amorphous silicon semiconductor, a monocrystalline silicon semiconductor, a polycrystalline silicon semiconductor, an oxide semiconductor, and the like.

The light emitting element LD may include the anode electrode AE, a cathode electrode CE, and a light emitting layer. The light emitting layer may be disposed between the anode electrode AE and the cathode electrode CE. After a data signal transferred through the jth data line DLj is reflected on a voltage of the second node N2, the fourth and sixth transistors T4 and T6 may be turned on when the emission control signals of the first and second sub-emission control lines SEL1 and SEL2 are enabled to a low level. The first transistor T1 may be turned on according to the voltage of the second node N2, and accordingly, a current may flow from the first power voltage node VDDN to a second power voltage node VSSN. The light emitting element LD may emit light according to an amount of the current flowing from the first power voltage node VDDN to the second power voltage node VSSN.

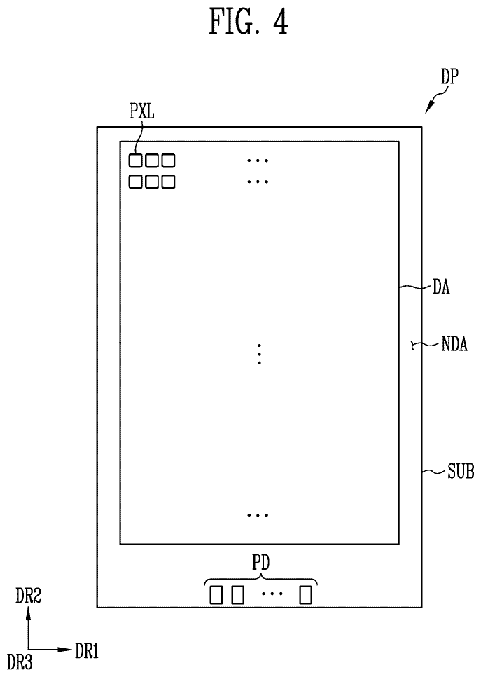

FIG. 4 is a plan view illustrating an embodiment of the display panel shown in FIG. 1. As used herein, the “plan view” is a view in a thickness direction (i.e., third direction DR3) of the display device 100.

Referring to FIG. 4, an embodiment DP of the display panel 110 shown in FIG. 1 may include a display area DA and a non-display area NDA. The display panel DP may display an image through the display area DA. The non-display area NDA may be disposed at the periphery of the display area DA.

The display panel DP may include a substrate SUB, pixels PXL, and pads PD. The pixels PXL may be disposed in the display area DA on the substrate SUB. The pixels PXL may be arranged in a matrix form along a first direction DR1 and a second direction DR2 intersecting the first direction DR1. However, embodiments are not limited thereto. The first direction DR1 may be a row direction, and the second direction DR2 may be a column direction.

A component for controlling the pixels PXL may be disposed in the non-display area NDA on the substrate SUB. For example, lines such as the first to mth gate lines GL1 to GLm and the first to nth data lines DL1 to DLn, which are shown in FIG. 1, may be disposed in the non-display area NDA.

At least one of the gate driver 120, the data driver 130, the voltage generator 140, the controller 150, and the temperature sensor 160, which are shown in FIG. 1, may be integrated in the non-display area NDA of the display panel DP. In an embodiment, the gate driver 120 shown in FIG. 1 may be mounted on the display panel DP, and be disposed in the non-display area NDA. In another embodiment, the gate driver 120 may be implemented as an integrated circuit distinguished from the display panel DP. In an embodiment, the temperature sensor 160 may be disposed in the non-display area NDA to sense a temperature of the display panel DP.

The pads PD may be disposed in the non-display area NDA on the substrate SUB. The pads PD may be electrically connected to the pixels PXL through the lines. For example, the pads PD may be connected to the pixels PXL through the first to nth data lines DL1 to DLn.

The pads PD may interface the display panel DP with other components of the display device 100 (see FIG. 1). In an embodiment, voltages and signals, which are for operations of components included in the display panel DP, may be provided from the driver integrated circuit DIC shown in FIG. 1 through the pads PD. For example, the first to nth data lines DL1 to DLn may be connected to the driver integrated circuit DIC through the pads PD. For example, the first and second power voltages VDD and VSS may be received from the driver integrated circuit DIC through the pads PD. When the gate driver 120 is mounted in the display panel DP, the gate control signal GCS may be transmitted from the driver integrated circuit DIC to the gate driver 120 through the pads PD.

In an embodiment, a circuit board may be electrically connected to the pads PD, using a conductive adhesive member such as an anisotropic conductive film. The circuit board may be a flexible printed circuit board (FPCB) or a flexible film, which has a flexible material. The driver integrated circuit DIC may be mounted on the circuit board to be electrically connected to the pads PD.

In an embodiment, the display area DA may have various shapes. The display area DA may have a closed-loop shape including linear sides and/or curved sides. For example, the display area DA may have shapes such as a polygon, a circle, a semicircle, and an ellipse.

In an embodiment, the display panel DP may have a flat display surface. In another embodiment, the display panel DP may have at least partially round display surface. In an embodiment, the display panel DP may be bendable, foldable or rollable. The display panel DP and/or the substrate SUB may include materials having flexibility.

FIG. 5 is a plan view illustrating an embodiment of the pixel shown in FIG. 4.

Referring to FIG. 5, a pixel PXL may include a first pixel PA and a second pixel PB. The first pixel PA may be a pixel having a relatively wide viewing angle. The second pixel PB may be a pixel having a viewing angle narrower than the viewing angle of the first pixel PA. The first pixel PA may emit light in the normal mode, and the second pixel PB may emit light in the privacy mode. In an example, the first pixel PA may not emit light in the privacy mode, and the second pixel PB may not emit light in the normal mode. Accordingly, an image having a normal viewing angle is displayed in the normal mode, and an image having a relatively limited viewing angle is displayed in the privacy mode, thereby preventing an image from being viewed in a specific direction of the display panel DP, e.g., at a side of the display panel DP. However, the operations in the normal mode and the privacy mode are not necessarily limited thereto. In some embodiments, both the first pixel PA and the second pixel PB may emit light in the normal mode.

The first pixel PA may include a first sub-pixel PA1, a second sub-pixel PA2, and a third sub-pixel PA3. The first sub-pixel PA1 of the first pixel PA may be spaced apart from the second sub-pixel PA2 of the first pixel PA in the second direction DR2. The third sub-pixel PA3 of the first pixel PA may be spaced apart from the first sub-pixel PA1 and the second sub-pixel PA2 of the first pixel PA in the first direction DR1.

The first sub-pixel PA1 of the first pixel PA may be an area in which light is emitted from a first light emitting layer ELA1 located in the first sub-pixel PA1. The first light emitting layer ELA1 of the first pixel PA may generate light of a first color, e.g., a red color. The first sub-pixel PA1 of the first pixel PA may be a sub-pixel of the first color, e.g., the red color.

The second sub-pixel PA2 of the first pixel PA may be an area in which light is emitted from a second light emitting layer ELA2 located in the second sub-pixel PA2. The second light emitting layer ELA2 of the first pixel PA may generate light of a second color, e.g., a green color. The second sub-pixel PA2 of the first pixel PA ma be a sub-pixel of the second color, e.g., the green color.

The third sub-pixel PA3 of the first pixel PA may be an area in which light is emitted from a third light emitting layer ELA3 located in the third sub-pixel PA3. The third light emitting layer ELA3 of the first pixel PA may generate light of a third color, e.g., a blue color. The third sub-pixel PA3 of the first pixel PA may be a sub-pixel of the third color, e.g., the blue color.

A size of the first sub-pixel PA1 of the first pixel PA may be smaller than a size of the second sub-pixel PA2 of the first pixel PA. The size of the second sub-pixel PA2 of the first pixel PA may be smaller than a size of the third sub-pixel PA3 of the first pixel PA. However, the sizes and shapes of the first to third sub-pixels PA1, PA2, and PA3 of the first pixel PA are not limited to the embodiment exemplified in FIG. 5, and the first to third sub-pixels PA1, PA2, and PA3 of the first pixel PA may be modified to have various sizes and various shapes.

The second pixel PB may include a first sub-pixel PB1, a second sub-pixel PB2, and a third sub-pixel PB3. The first sub-pixel PB1 of the second pixel PB may be spaced apart from the second sub-pixel PB2 of the second pixel PB in the second direction DR2. The third sub-pixel PB3 of the second pixel PB may be spaced apart from the first sub-pixel PB1 and the second sub-pixel PB2 of the second pixel PB in the first direction DR1.

The first sub-pixel PB1 of the second pixel PB may be disposed at one side of the first sub-pixel PA1 of the first pixel PA. For example, the first sub-pixel PA1 of the first pixel PA may be disposed between the first sub-pixel PB1 and the third sub-pixel PB3 of the second pixel PB.

The second sub-pixel PB2 of the second pixel PB may be disposed at one side of the second sub-pixel PA2 of the first pixel PA. For example, the second sub-pixel PA2 of the first pixel PA may be disposed between the second sub-pixel PB2 and the third sub-pixel PB3 of the second pixel PB.

The third sub-pixel PB3 of the second pixel PB may be disposed at one side of the third sub-pixel PA3 of the first pixel PA. For example, the third sub-pixel PA3 of the first pixel PA may be disposed between the first sub-pixel PA1 and the third sub-pixel PA3 of the first pixel PA and between the second sub-pixel PA2 and the third sub-pixel PA3 of the first pixel PA.

The first sub-pixel PB1 of the second pixel PB may be an area in which light is emitted from a first light emitting layer ELB1 located in the first sub-pixel PB1. The first light emitting layer ELB1 of the second pixel PB may generate light of the first color, e.g., the red color. The first sub-pixel PB1 of the second pixel PB may emit light of the same color as the first sub-pixel PA1 of the first pixel PA. In an example, the first sub-pixel PB1 of the second pixel PB may be a sub-pixel of the first color, e.g., the red color.

The second sub-pixel PB2 of the second pixel PB may be an area in which light is emitted from a second light emitting layer ELB2 located in the second sub-pixel PB2. The second light emitting layer ELB2 of the second pixel PB may generate light of the second color, e.g., the green color. The second sub-pixel PB2 of the second pixel PB may emit light of the same color as the second sub-pixel PA2 of the first pixel PA. In an example, the second sub-pixel PB2 of the second pixel PB may be a sub-pixel of the second color, e.g., the green color.

The third sub-pixel PB3 of the second pixel PB may be an area in which light is emitted from a third light emitting layer ELB3 located in the third sub-pixel PB3. The third light emitting layer ELB3 of the second pixel PB may generate light of the third color, e.g., the blue color. The third sub-pixel PB3 of the second pixel PB may emit light of the same color as the third sub-pixel PA3 of the first pixel PA. In an example, the third sub-pixel PB3 of the second pixel PB may be a sub-pixel of the third color, e.g., the blue color.

A size of the first sub-pixel PB1 of the second pixel PB may be smaller than a size of the second sub-pixel PB2 of the second pixel PB. The size of the second sub-pixel PB2 of the second pixel PB may be smaller than a size of the third sub-pixel PB3 of the second pixel PB. However, the sizes and shapes of the first to third sub-pixels PB1, PB2, and PB3 of the second pixel PB are not limited to the embodiment exemplified in FIG. 5, and the first to third sub-pixels PB1, PB2, and PB3 of the second pixel PB may be modified to have various sizes and various shapes.

In an embodiment, the pixel PXL may further include light blocking layers BM1 and BM2 for limiting a viewing angle of the second pixel PB in the privacy mode. The light blocking layers BM1 and BM2 may include first light blocking layers BM1 and second light blocking layers BM2. Each of the first light blocking layers BM1 and the second light blocking layers BM2 may extend along the second direction DR2 in a plan view, and the first light blocking layers BM1 and the second light blocking layers BM2 may be spaced apart from each other along the first direction DR1.

The first light blocking layers BM1 may be disposed in a non-emission area NEA. The first light blocking layers BM1 may be disposed between some of the sub-pixels PA1, PA2, and PA3 (or the light emitting layers ELA1, ELA2, and ELA3) of the first pixel PA and some of the sub-pixels PB1, PB2, and PB3 (or the light emitting layers ELB1, ELB2, and ELB3) of the second pixel PB. The first light blocking layers BM1 may not overlap with the sub-pixels PA1, PA2, and PA3 (or the light emitting layers ELA1, ELA2, and ELA3) of the first pixel PA in a plan view. In an embodiment, the first light blocking layers BM1 may not overlap with the sub-pixels PB1, PB2, and PB3 (or the light emitting layers ELB1, ELB2, and ELB3) of the second pixel PB in a plan view, but the present disclosure is not necessarily limited thereto.

At least one first light blocking layer BM1 may be disposed between the first sub-pixel PA1 of the first pixel PA and the third sub-pixel PB3 of the second pixel PB and between the second sub-pixel PA2 of the first pixel PA and the third sub-pixel PB3 of the second pixel PB. At least one first light blocking layer BM1 may be dispose between the third sub-pixel PA3 of the first pixel PA and the first sub-pixel PB1 of the second pixel PB and between the third sub-pixel PA3 of the first pixel PA and the second sub-pixel PB2 of the second pixel PB.

The second light blocking layers BM2 may overlap with the sub-pixels PB1, PB2, and PB3 (or the light emitting layers ELB1, ELB2, and ELB3) of the second pixel PB in a plan view. In an example, at least one second light blocking layer BM2 may overlap with the first sub-pixel PB1 and the second sub-pixel PB2 of the second pixel PB2 in a plan view. At least one second light blocking layer BM2 may overlap with the third sub-pixel PB3 of the second pixel PB in a plan view.

In an embodiment, the pixel PXL may include a lens LS for controlling an optical path of the second pixel PB. The lens LS may allow light emitted from the second pixel PB to be output to the front of the display device 100 by reflecting or refracting the light, so that leakage of light having a high viewing angle (e.g., 35 degrees) in the privacy mode can be reduced, and front light output efficiency can be effectively improved. The light blocking layers BM1 and BM2 may also allow light emitted from the second pixel PB to be output to the front of the display device 100 by reflecting the light.

The lens LS may be disposed in the non-emission area NEA. The lens LS may be disposed on side surfaces of the light blocking layers BM1 and BM2. The lens LS may be disposed on a side surface of each of the first light blocking layers BM1. The lens LS may be disposed between some of the sub-pixels PA1, PA2, and PA3 (or the light emitting layers ELA1, ELA2, and ELA3) of the first pixel PA and the first light blocking layers BM1 in a plan view. The lens LS may be spaced apart from the sub-pixels PA1, PA2, and PA3 (or the light emitting layers ELA1, ELA2, and ELA3) of the first pixel PA in a plan view. The lens LS may not overlap with the sub-pixels PA1, PA2, and PA3 (or the light emitting layers ELA1, ELA2, and ELA3) of the first pixel PA in a plan view. The lens LS may not overlap with the sub-pixels PB1, PB2, and PB3 (or the light emitting layers ELB1, ELB2, and ELB3) of the second pixel PB in a plan view.

The lens LS may include first to third lenses LS1, LS2, and LS3 disposed on side surfaces of the first light blocking layers BM1. The first lens LS1 may be disposed between the first sub-pixel PA1 (or the first light emitting layer ELA1) of the first pixel PA1 and a first light blocking layer BM1 in a plan view. The first lens LS1 may extend along the second direction DR2 in a plan view, but the present disclosure is not necessarily limited thereto. The first lens LS1 may allow light emitted from the first sub-pixel PB1 (or the first light emitting layer ELB1) of the second pixel PB to be output to the front of the display device 100 by reflecting or refracting the light, so that leakage of light having a high viewing angle in the privacy mode can be reduced, and front light output efficiency can be effectively improved.

The second lens LS2 may be disposed between the second sub-pixel PA2 (or the second light emitting layer ELA2) of the first pixel PA and the first light blocking layer BM1 in a plan view. The second lens LS2 may extend along the second direction DR2 in a plan view, but the present disclosure is not necessarily limited thereto. The second lens LS2 may allow light emitted from the second sub-pixel PB2 (or the second light emitting layer ELB2) of the second pixel PB to be output to the front of the display device 100 by reflecting or refracting the light, so that leakage of light having a high viewing angle in the privacy mode can be reduced, and front light output efficiency can be effectively improved. In the drawing, a structure in which the first lens LS1 and the second lens LS2 are spaced apart from each other in the second direction DR2 is exemplified. However, the present disclosure is not necessarily limited thereto. In some embodiments, the first lens LS1 and the second lens LS2 may be integrally formed.

The third lens LS3 may be disposed between the third sub-pixel PA3 (or the third light emitting layer ELA3) of the first pixel PA and a first light blocking layer BM1 in a plan view. The third lens LS3 may extend along the second direction DR2 in a plan view, but the present disclosure is not necessarily limited thereto. The third lens LS3 may be spaced apart from the first lens LS1 and the second lens LS2 in the first direction DR1, but the present disclosure is not necessarily limited thereto. The third lens LS3 may allow light emitted from the third sub-pixel PB3 (or the third light emitting layer ELB3) of the second pixel PB to be output to the front of the display device 100 by reflecting or refracting the light, so that leakage of light having a high viewing angle in the privacy mode can be reduced, and front light output efficiency can be effectively improved. The light blocking layers BM1 and BM2 may also allow light emitted from the second pixel PB to be output to the front of the display device 100 by reflecting the light.

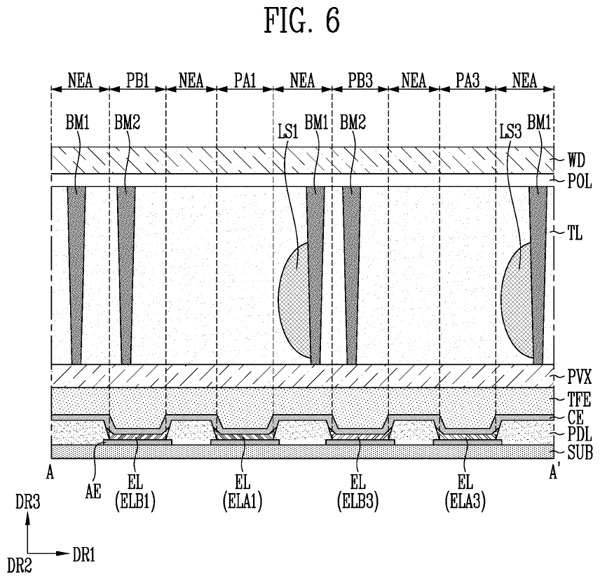

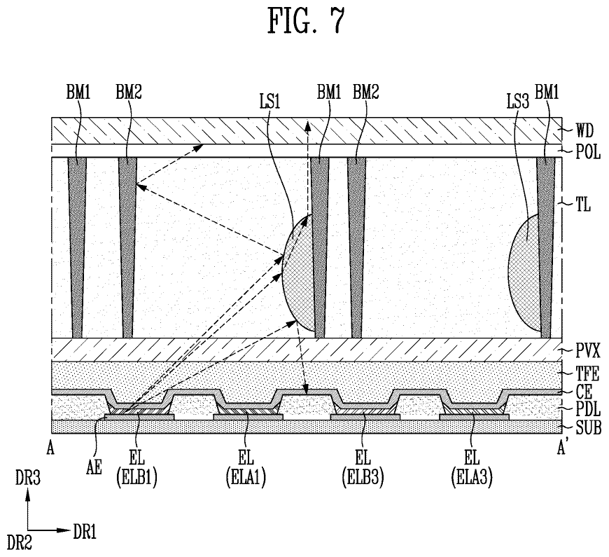

FIGS. 6 and 7 are sectional views taken along line A-A′ shown in FIG. 5.

Referring to FIGS. 6 and 7, a display layer AE, EL, and CE may be disposed on a substrate SUB. The substrate SUB may include a base layer and a circuit layer. The base layer may be formed of polyimide (PI), glass, a silicon wafer, or the like. The circuit layer may include conductive patterns and insulating layers, and the conductive patterns may serve as a pixel circuit (see SPC shown in FIG. 2) and various lines. The circuit layer may include transistors and one or more capacitors. Each transistor may include a semiconductor portion including a source region, a drain region, and a channel region, and a gate electrode overlapping with the semiconductor portion in a plan view. Each capacitor may include electrodes spaced apart from each other in a third direction DR3 with an insulating layer interposed therebetween. Lines of the circuit layer may include signal lines, e.g., a gate line, an emission control line, a data line, and the like.

The display layer AE, EL, and CE may include anode electrodes (or first electrodes) AE, light emitting layers EL, and/or a cathode electrode (or second electrode) CE. The anode electrodes AE may be electrically connected to the circuit layer of the substrate SUB. The anode electrodes AE may include an opaque conductive material capable of reflecting light, but embodiments are not limited thereto.

The anode electrodes AE may be disposed in the sub-pixels PA1, PA2, PA3, PB1, PB2, and PB3 of the first and second pixels PA and PB, respectively. The anode electrodes AE may have shapes similar to shapes of the sub-pixels PA1, PA2, PA3, PB1, PB2, and PB3 of the first and second pixels PA and PB in a plan view, respectively.

A pixel defining layer PDL may be disposed on the anode electrodes AE. The pixel defining layer PDL may be disposed in the non-emission area NEA. The pixel defining layer PDL may include openings exposing portions of the anode electrodes AE, respectively. The openings of the pixel defining layer PDL may define the sub-pixels PA1, PA2, PA3, PB1, PB2, and PB3 of the first and second pixels PA and PB.

The light emitting layers EL may be disposed on the anode electrodes AE and the pixel defining layer PDL. The light emitting layers EL may be disposed in the sub-pixels PA1, PA2, PA3, PB1, PB2, and PB3 of the first and second pixels PA and PB, respectively.

The first light emitting layer ELA1 of the first pixel PA and the first light emitting layer ELB1 of the second pixel PB may be disposed in the same layer, and be simultaneously formed through the same process. However, the present disclosure is not necessarily limited thereto. The first light emitting layer ELA1 of the first pixel PA and the first light emitting layer ELB1 of the second pixel PB may generate light of the first color, e.g., the red color.

The second light emitting layer ELA2 of the first pixel PA and the second light emitting layer ELB2 of the second pixel PB may be disposed in the same layer, and be simultaneously formed through the same process. However, the present disclosure is not necessarily limited thereto. The second light emitting layer ELA2 of the first pixel PA and the second light emitting layer ELB2 of the second pixel PB may generate light of the second color, e.g., the green color.

The third light emitting layer ELA3 of the first pixel PA and the third light emitting layer ELB3 of the second pixel PB may be disposed in the same layer, and be simultaneously formed through the same process. However, the present disclosure is not necessarily limited thereto. The third light emitting layer ELA3 of the first pixel PA and the third light emitting layer ELB3 of the second pixel PB may generate light of the third color, e.g., the blue color.

The cathode electrode CE may be disposed on the light emitting layers EL. The cathode electrode CE may be disposed in an entirety of the first pixel PA and the second pixel PB. The cathode electrode CE may serve as a half mirror which allows light emitted from the light emitting layer EL to be partially transmitted therethrough and to be partially reflected therefrom. For example, the cathode electrode CE may be formed of a metal material to have a relatively thin thickness or be formed of a transparent conductive material. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, and gallium tin oxide. In other embodiments, the cathode electrode CE may include at least one of silver (Ag), magnesium (Mg), and mixtures thereof. However, the material of the cathode electrode CE is not limited thereto.

An encapsulation layer TFE may be disposed over the cathode electrode CE. The encapsulation layer TFE may prevent oxygen and/or moisture from infiltrating into the light emitting layer. The encapsulation layer TFE may include a structure in which at least one inorganic layer and at least one organic layer are alternately stacked. The inorganic layer may include silicon nitride, silicon oxide, silicon oxynitride (SiOₓN_{y}), or the like. The organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

A protective layer PVX may be disposed on the encapsulation layer TFE. The protective layer PVX may be formed of an organic layer. The organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). In some embodiments, the protective layer PVX may be formed of an inorganic layer. The inorganic layer may include silicon nitride, silicon oxide, silicon oxynitride (SiOₓN_{y}), or the like. However, the materials of the organic layer and the inorganic layer of the protective layer PVX are not limited thereto.

A transmission layer TL may be disposed on the protective layer PVX. The transmission layer TL may be disposed directly on the protective layer PVX. The transmission layer TL may be in contact with the protective layer PVX. In some embodiments, when the protective layer PVX is omitted, the transmission layer TL may be disposed on the encapsulation layer TFE. The transmission layer TL may be disposed directly on the encapsulation layer TFE to be in contact with the encapsulation layer TFE. The transmission layer TL may be entirely disposed in the first pixel PA, the second pixel PB, and/or the non-emission area NEA.

The transmission layer TL may be formed of a transparent material capable of allow the light to be transmitted therethrough. A refractive index of the transmission layer TL may be 1.6 to 1.8. The transmission layer TL may be formed of an organic layer. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB), but the present disclosure is not necessarily limited thereto.

Light blocking layers BM1 and BM2 may be disposed in the transmission layer TL. In an example, trenches may be formed in the transmission layer TL, and the light blocking layers BM1 and BM2 may be disposed in the trenches. The trenches may have a shape recessed in the opposite direction of the third direction DR3 with respect to a top surface of the transmission layer TL. In an example, the trenches may expose a layer (e.g., the protective layer PVX) disposed under the transmission layer TL while penetrating the transmission layer TL. The light blocking layers BM1 and BM2 limit the viewing angle of the second pixel PB, thereby minimizing that an image is viewed at a side. Accordingly, the privacy mode can be implemented.

First light blocking layers BM1 may be disposed in the non-emission area NEA. The first light blocking layers BM1 may be disposed on the pixel defining layer PDL. The first light blocking layers BM1 may overlap with the pixel defining layer PDL in the third direction DR3.

The first light blocking layers BM1 may not overlap with the sub-pixels PA1, PA2, and PA3 (or the light emitting layers ELA1, ELA2, and ELA3) of the first pixel PA in the third direction DR3. In an embodiment, the first light blocking layers BM1 may not overlap with the sub-pixels PB1, PB2, and PB3 (or the light emitting layers ELB1, ELB2, and ELB3) of the second pixel PB in the third direction DR3, but the present disclosure is not necessarily limited thereto.

Second light blocking layers BM2 may be disposed on the sub-pixels PB1, PB2, and PB3 (or the light emitting layers ELB1, ELB2, and ELB3) of the second pixel PB. The second light blocking layers BM2 may overlap with the sub-pixels PB1, PB2, and PB3 (or the light emitting layers ELB1, ELB2, and ELB3) of the second pixel PB in the third direction DR3. In an example, at least one second light blocking layer BM2 may overlap with the first sub-pixel PB1 and the second sub-pixel PB2 of the second pixel PB in the third direction DR3. At least one second light blocking layer BM2 may overlap with the third sub-pixel PB3 of the second pixel PB in the third direction DR3.

The lens LS may be disposed in the transmission layer TL. A refractive index of the lens LS may be smaller than the refractive index of the transmission layer TL. For example, the refractive index of the lens LS may be 1.4 to 1.6, but the present disclosure is not necessarily limited thereto.

The lens LS may be disposed in the non-emission area NEA. The lens LS may be disposed on the pixel defining layer PDL. The lens LS may overlap with the pixel defining layer PDL in the third direction DR3. The lens LS may not overlap with the sub-pixels PA1, PA2, and PA3 (or the light emitting layers ELA1, ELA2, and ELA3) of the first pixel PA in the third direction DR3. The lens LS may not overlap with the sub-pixels PB1, PB2, and PB3 (or the light emitting layers ELB1, ELB2, and ELB3) of the second pixel PB in the third direction DR3.

The lens LS may be disposed on side surfaces of the light blocking layers BM1 and BM2. For example, the lens LS may be disposed on side surfaces of the first light blocking layers BM1. The lens LS may be disposed directly on the side surfaces of the first light blocking layers BM1. The lens LS may be in contact with the side surfaces of the first light blocking layers BM1.

Each of the first light blocking layers BM1 may include a first side surface and a second side surface. The first side surfaces of the first light blocking layers BM1 may be adjacent to the sub-pixels PA1, PA2, and PA3 of the first pixel PA. The first side surfaces of the first light blocking layers BM1 may face the sub-pixels PA1, PA2, and PA3 of the first pixel PA.

The second side surfaces of the first light blocking layers BM1 may be adjacent to the sub-pixels PB1, PB2, and PB3 of the second pixel PB. The second side surfaces of the first light blocking layers BM1 may face the sub-pixels PB1, PB2, and PB3 of the second pixel PB. The second side surface of each of the first light blocking layers BM1 may be adjacent to the second light blocking layer BM2. The second side surface of each of the first light blocking layers BM1 may face the second light blocking layer BM2.

In an embodiment, the lens LS may be disposed on only the first side surface of each of the first light blocking layer BM1. The lens LS may be in contact with the first side surface of each of the first light blocking layer BM1. When the lens LS is provided on the first side surface of each of the first light blocking layer BM1, light emitted from the second pixel PB may be reflected by the first side surface of each of the first light blocking layers BM1, to prevent leakage of light having a high viewing angle from being caused. Specifically, the lens LS may function to allow light emitted from the second pixel PB to progress toward the first light blocking layer BM1 to be output to the front of the display device 100 by reflecting or refracting the light. Accordingly, front light output efficiency can be effectively improved, and a viewing angle in the privacy mode can be easily controlled by reducing leakage of light having a high viewing angle in the privacy mode.

In an embodiment, the lens LS may not be provided on the second side surface of each of the first light blocking layers BM1. When the lens LS is provided on the second side surface of each of the first light blocking layers BM1, it is difficult to implement the lens LS in a distance condition (e.g., 3 μm or less) of light blocking layers BM1 and BM2 of a high-resolution display device, and therefore, fairness may be deteriorated.

In an embodiment, the lens LS may not be provided on side surfaces of the second light blocking layers BM2. When the lens LS is disposed on the side surfaces of the second light blocking layers BM2, the lens LS overlaps with the sub-pixels PB1, PB2, and PB3 (or the light emitting layers ELB1, ELB2, and ELB3) of the second pixel PB, and therefore, front luminance loss may occur.

The lens LS may have an asymmetrical shape in a cross-sectional view. In an example, one side surface at which the lens LS is adjacent to (or in contact with) the transmission layer TL may be a curved surface, and the other side surface at which the lens LS is adjacent to (or in contact with) the first light blocking layer BM1 may be a flat surface.

A polarizing layer POL may be disposed on the transmission layer TL, the light blocking layers BM1 and BM2, and/or the lens LS. The polarizing layer POL may function to prevent external light reflection. The polarizing layer POL may be omitted in some embodiments.

A window WD may be disposed on the polarizing layer POL. The window WD may be provided at an upper portion of the display panel DP to protect the display panel DP from external impact, moisture, heat, and the like. The window WD may be made of a transparent material such that light emitted from the display panel DP can be transmitted therethrough.

In an embodiment, the window WD may have a multi-layer structure selected from a glass substrate, a plastic film, and a plastic substrate. The multi-layer structure may be formed through a continuous process or an adhesion process using an adhesive layer. The whole or a portion of the window WD may have flexibility.

Hereinafter, another embodiment will be described. In the following embodiment, components identical to those which have already been described are designated by like reference numerals, and overlapping descriptions will be omitted or simplified.

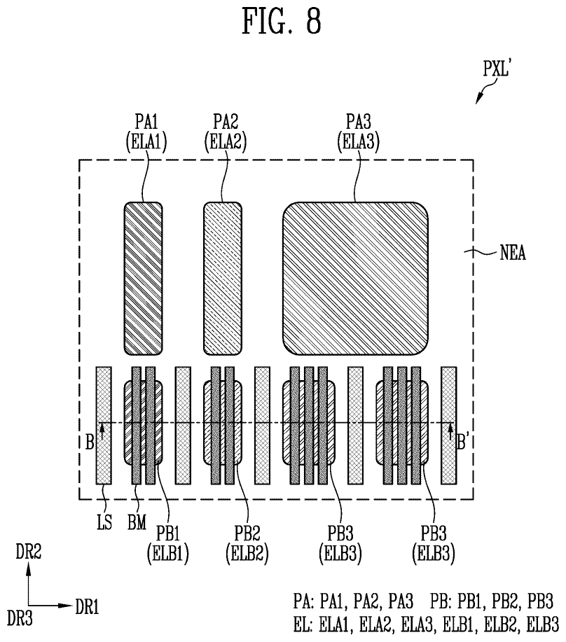

FIG. 8 is a plan view illustrating another embodiment of the pixel shown in FIG. 4.

Referring to FIG. 8, a pixel PXL′ may include a first pixel PA and a second pixel PB. The first pixel PA may be a pixel having a relatively wide viewing angle. The second pixel PB may be a pixel having a viewing angle narrower than the viewing angle of the first pixel PA. The first pixel PA may emit light in the normal mode, and the second pixel PB may emit light in the privacy mode. In an example, the first pixel PA may not emit light in the privacy mode, and the second pixel PB may not emit light in the normal mode. Accordingly, an image having a normal viewing angle is displayed in the normal mode, and an image having a relatively limited viewing angle is displayed in the privacy mode, thereby preventing an image from being viewed in a specific direction of the display panel DP, e.g., at a side of the display panel DP. However, the operations in the normal mode and the privacy mode are not necessarily limited thereto. In some embodiments, both the first pixel PA and the second pixel PB may emit light in the normal mode.

The first pixel PA may include a first sub-pixel PA1, a second sub-pixel PA2, and a third sub-pixel PA3. The first sub-pixel PA1, the second sub-pixel PA2, and the third sub-pixel PA3 of the first pixel PA may be sequentially disposed along the first direction DR1.

The first sub-pixel PA1 of the first pixel PA may be an area in which light is emitted from a first light emitting layer ELA1 located in the first sub-pixel PA1. The first light emitting layer ELA1 of the first pixel PA may generate light of a first color, e.g., a red color. The first sub-pixel PA1 of the first pixel PA may be a sub-pixel of the first color, e.g., the red color.

The second sub-pixel PA2 of the first pixel PA may be an area in which light is emitted from a second light emitting layer ELA2 located in the second sub-pixel PA2. The second light emitting layer ELA2 of the first pixel PA may generate light of a second color, e.g., a green color. The second sub-pixel PA2 of the first pixel PA may be a sub-pixel of the second color, e.g., the green color.

The third sub-pixel PA3 of the first pixel PA may be an area in which light is emitted from a third light emitting layer ELA3 located in the third sub-pixel PA3. The third light emitting layer ELA3 of the first pixel PA may generate light of a third color, e.g., a blue color. The third sub-pixel PA3 of the first pixel PA may be a sub-pixel of the third color, e.g., the blue color.

A size of the first sub-pixel PA1 of the first pixel PA and a size of the second sub-pixel PA2 of the first pixel PA may be the same. A size of the third sub-pixel PA3 of the first pixel PA may be larger than the size of the first sub-pixel PA1 and/or the size of the second sub-pixel PA2. However, the sizes and shapes of the first to third sub-pixels PA1, PA2, and PA3 of the first pixel PA are not limited to the embodiment exemplified in FIG. 8, and the first to third sub-pixels PA1, PA2, and PA3 of the first pixel PA may be modified to have various sizes and various shapes.

The second pixel PB may include a first sub-pixel PB1, a second sub-pixel PB2, and a third sub-pixel PB3. The first sub-pixel PB1, the second sub-pixel PB2, and the third sub-pixel PB3 of the second pixel PB may be sequentially disposed along the first direction DR1. The first sub-pixel PB1, the second sub-pixel PB2, and the third sub-pixel PB3 of the second pixel PB may be spaced apart from the first sub-pixel PA1, the second sub-pixel PA2, and the third sub-pixel PA3 of the first pixel PA in the second direction DR2, respectively. A plurality of third sub-pixels PB3 may be provided. In an example, two third sub-pixels PB3 may be provided. The two third sub-pixels PB3 may be spaced apart from each other in the first direction DR1.

The first sub-pixel PB1 of the second pixel PB may be an area in which light is emitted from a first light emitting layer ELB1 located in the first sub-pixel PB1. The first light emitting layer ELB1 of the second pixel PB may generate light of the first color, e.g., the red color. The first sub-pixel PB1 of the second pixel PB may emit light of the same color as the first sub-pixel PA1 of the first pixel PA. In an example, the first sub-pixel PB1 of the second pixel PB may be a sub-pixel of the first color, e.g., the red color.

The second sub-pixel PB2 of the second pixel PB may be an area in which light is emitted from a second light emitting layer ELB2 located in the second sub-pixel PB2. The second light emitting layer ELB2 of the second pixel PB may generate light of the second color, e.g., the green color. The second sub-pixel PB2 of the second pixel PB may emit light of the same color as the second sub-pixel PA2 of the first pixel PA. In an example, the second sub-pixel PB2 of the second pixel PB may be a sub-pixel of the second color, e.g., the green color.

The third sub-pixel PB3 of the second pixel PB may be an area in which light is emitted from a third light emitting layer ELB3 located in the third sub-pixel PB3. The third light emitting layer ELB3 of the second pixel PB may generate light of the third color, e.g., the blue color. The third sub-pixel PB3 of the second pixel PB may emit light of the same color as the third sub-pixel PA3 of the first pixel PA. In an example, the third sub-pixel PB3 of the second pixel PB may be a sub-pixel of the third color, e.g., the blue color.

A size of the first sub-pixel PB1 of the second pixel PB and a size of the second sub-pixel PB2 of the second pixel PB may be the same. A size of the third sub-pixel PB3 of the second pixel PB may be larger than the size of the first sub-pixel PB1 and/or the size of the second sub-pixel PB2. The size of the first sub-pixel PB1 of the second pixel PB may be smaller than the size of the first sub-pixel PA1 of the first pixel PA. The size of the second sub-pixel PB2 of the second pixel PB may be smaller than the size of the second sub-pixel PA2 of the first pixel PA. The size of the third sub-pixel PB3 of the second pixel PB may be smaller than the size of the third sub-pixel PA3 of the first pixel PA. As such, the sizes of the sub-pixels PB1, PB2, and PB3 of the second pixel PB are formed relatively small, so that a viewing angle is limited thereby minimizing that an image is viewed at a side. Accordingly, the privacy mode can be easily implemented. However, the sizes and shapes of the first to third sub-pixels PB1, PB2, and PB3 of the second pixel PB are not limited to the embodiment exemplified in FIG. 8, and the first to third sub-pixels PB1, PB2, and PB3 of the second pixel PB may be modified to various sizes and various shapes.

In an embodiment, the pixel PXL′ may further include light blocking layers BM for limiting a viewing angle of the second pixel PB. Each of the light blocking layers BM may extend along the second direction DR2 in a plan view, and the light blocking layers BM may be spaced apart from each other along the first direction DR1.

The light blocking layers BM may be disposed in the second pixel PB. The light blocking layers BM may not overlap with the first pixel PA in a plan view. The light blocking layers BM may overlap with the sub-pixels PB1, PB2, and PB3 (or the light emitting layers ELB1, ELB2, and ELB3) of the second pixel PB in a plan view, respectively. In the drawing, an embodiment in which two light blocking layers BM overlap with the first sub-pixel PB1 (or the first light emitting layer ELB1) of the second pixel PB, two light blocking layers BM overlap with the second sub-pixel PB2 (or the second light emitting layer ELB2) of the second pixel PB, and three light blocking layers BM overlap with the third sub-pixel PB3 (or the third light emitting layer ELB3) of the second pixel PB in a plan view is exemplified. However, the present disclosure is not necessarily limited thereto.

In an embodiment, the pixel PXL′ may include lenses LS for controlling an optical path of the second pixel PB. In an example, the lens LS allows light emitted from the second pixel PB to be output to the front of the display device 100 by reflecting or refracting the light, so that leakage of light having a high viewing angle in the privacy mode can be reduced, and front light output efficiency can be effectively improved. The lenses LS may be disposed in the non-emission area NEA. The lenses LS may be disposed between the light blocking layers BM. Each of the lenses LS may extend along the second direction DR2, and the lenses LS may be spaced apart from each other along the first direction DR1.

The lenses LS may be disposed between the sub-pixels PB1, PB2, and PB3 (or the light emitting layers ELB1, ELB2, and ELB3) of the second pixel PB in a plan view, respectively. The lenses LS may not overlap with the sub-pixels PB1, PB2, and PB3 (or the light emitting layers ELB1, ELB2, and ELB3) of the second pixel PB in a plan view. The lenses LS may be disposed only between the sub-pixels PB1, PB2, and PB3 (or the light emitting layers ELB1, ELB2, and ELB3) of the second pixel PB in a plan view. That is, the lenses LS may not be disposed between the sub-pixels PA1, PB2, and PB3 (or the light emitting layers ELA1, ELA2, and ELA3) of the first pixel PA in a plan view. The lenses LS may not overlap with the sub-pixels PA1, PB2, and PB3 (or the light emitting layers ELA1, ELA2, and ELA3) of the first pixel PA in a plan view. The lenses LS may not overlap with the sub-pixels PB1, PB2, and PB3 (or the light emitting layers ELB1, ELB2, and ELB3) of the second pixel PB in the third direction DR3.

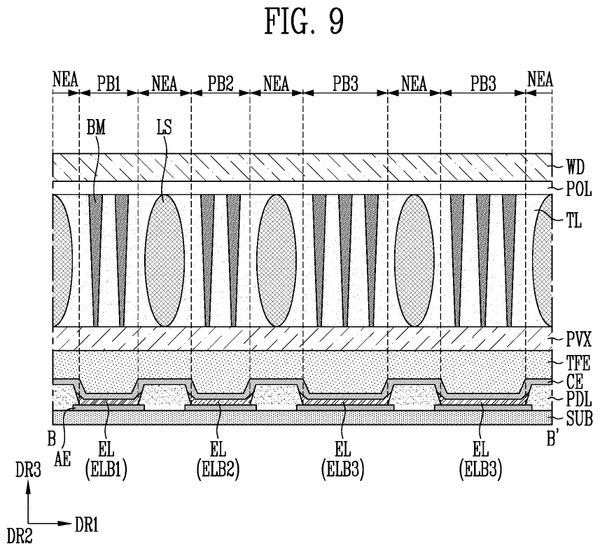

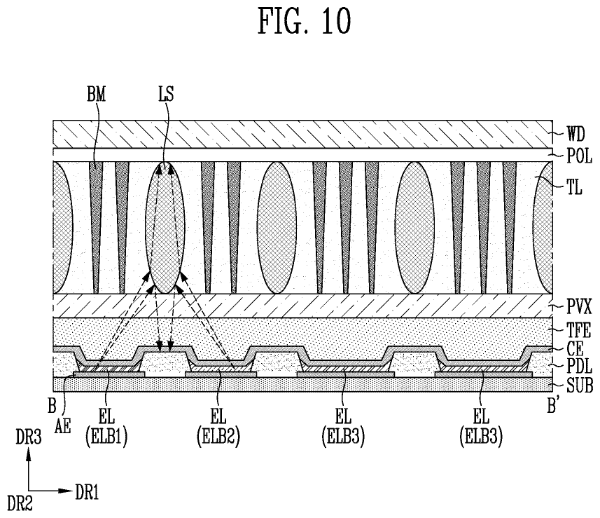

FIGS. 9 and 10 are sectional views taken along line B-B′ shown in FIG. 8.

Referring to FIGS. 9 and 10, a display layer AE, EL, and CE may be disposed on a substrate USB. An encapsulation layer TFE and/or a protective layer PVX may be disposed over the display layer AE, EL, and CE. The substrate SUB, the display layer AE, EL, and CE, the encapsulation layer TFE and/or the protective layer PVX have been described with reference to FIGS. 6 and 7, and therefore, overlapping descriptions will be omitted.

A transmission layer TL may be disposed on the protective layer PVX. The transmission layer TL may be entirely disposed in the first pixel PA, the second pixel PB, and/or the non-emission area NEA. In an embodiment, the transmission layer TL may be formed of an organic layer. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB), but the present disclosure is not necessarily limited thereto.

Light blocking layers BM may be disposed in the transmission layer TL. In an example, trenches may be formed in the transmission layer TL, and the light blocking layers BM may be disposed in the trenches. The trenches may have a shape recessed in the opposite direction of the third direction DR3 with respect to a top surface of the transmission layer TL. In an example, the trenches may expose a layer (e.g., the protective layer PVX) disposed under the transmission layer TL while penetrating the transmission layer TL. The light blocking layers BM limit the viewing angle of the second pixel PB, thereby minimizing that an image is viewed at a side. Accordingly, the privacy mode can be easily implemented.

The light blocking layers BM may be disposed on the sub-pixels PB1, PB2, and PB3 (or the light emitting layers ELB1, ELB2, and ELB3) of the second pixel PB. The light blocking layers BM may overlap with the sub-pixels PB1, PB2, and PB3 (or the light emitting layers ELB1, ELB2, and ELB3) of the second pixel PB in the third direction DR3. In the drawings, an embodiment in which two light blocking layers BM overlap with the first sub-pixel PB1 (or the first light emitting layer ELB1) of the second pixel PB in the third direction DR3, two light blocking layers BM overlap with the second sub-pixel PB2 (or the second light emitting layer ELB2) of the second pixel PB in the third direction DR3, and three light blocking layers BM overlap with the third sub-pixel PB3 (or the third light emitting layer ELB3) of the second pixel PB in the third direction DR3 is exemplified. However, the present disclosure is not necessarily limited thereto.

A lens LS may be disposed in the transmission layer TL. The transmission layer TL may surround the lens LS. The transmission layer TL may surround an entirety of the lens LS. The transmission layer TL may be disposed between the lens LS and the light blocking layer BM. The lens LS may be in contact with the transmission layer TL. A refractive index of the lens LS may be different from a refractive index of the transmission layer TL. The refractive index of the lens LS may be smaller than the refractive index of the transmission layer TL. For example, the refractive index of the lens LS may be 1.4 to 1.6, but the present disclosure is not necessarily limited thereto.

The lens LS may be disposed in the non-emission area NEA. The lens LS may be disposed above a pixel defining layer PDL. The lens LS may overlap with the pixel defining layer PDL in the third direction DR3. The lens LS may not overlap with the sub-pixels PA1, PA2, and PA3 (or the light emitting layers ELA1, ELA2, and ELA3) of the first pixel PA in the third direction DR3. The lens LS may not overlap with the sub-pixels PB1, PB2, and PB3 (or the light emitting layers ELB1, ELB2, and ELB3) of the second pixel PB in the third direction DR3.

A polarizing layer POL and/or a window WD may be disposed on the light blocking layers BM and/or the lens LS. The polarizing layer POL may function to prevent external light reflection. The window WD may be provided at an upper portion of the display panel DP to protect the display panel DP from external impact, moisture, heat, and the like.

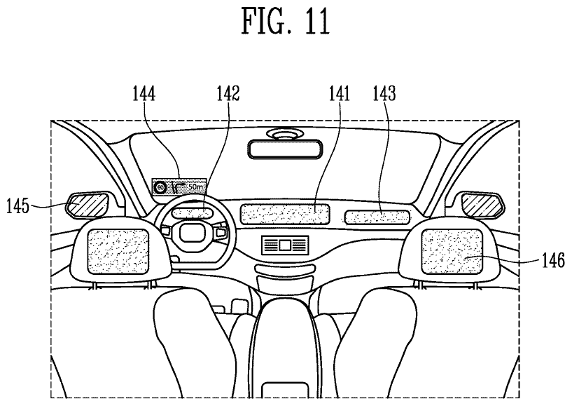

FIG. 11 is a perspective view illustrating an application example of the display device.

Referring to FIG. 11, the display device in accordance with the above-described embodiment may be applied to an automotive display. In an example, the automotive display may mean an electronic device provided at the inside/outside of a vehicle to provide image data.

For example, the display device may be applied to at least one of an infortainment panel 141, a cluster 142, a co-driver display 143, a head-up display 144, a side mirror display 145, and a rear seat display 146, which are provided in the vehicle. In an example, the display device may be applied to the co-driver display 143 to be switched to the privacy mode in driving. Since the co-driver display 143 is not viewed from a driver's seat, driver's looking aside can be prevented even when a passenger-seat passenger uses the display during driving. Meanwhile, the automotive display is not limited to the embodiment shown in FIG. 11, and the infortainment panel 141, the cluster 142, and/or co-driver display 143 may be integrally formed into a single display. A driver's seat area may be implemented in the normal mode, and the passenger seat area may be implemented such that a switch between the normal mode and the privacy mode is possible.

Continuously, a method of manufacturing the display device in accordance with the above-described embodiment will be described.

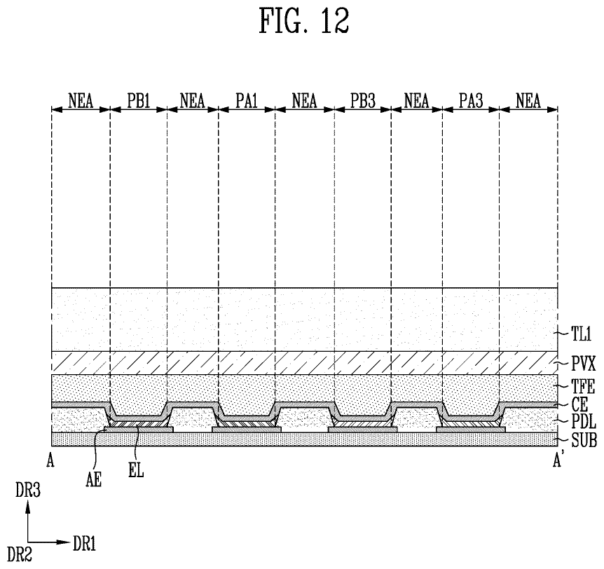

FIGS. 12 to 17 are sectional views illustrating process steps of a method of manufacturing a display device in accordance with an embodiment of the present disclosure. FIGS. 12 to 17 are sectional views illustrating a method of manufacturing the display device shown in FIGS. 5 to 7. For convenience of description, configurations shown in FIGS. 12 to 17 are briefly illustrated, and detailed reference numerals are omitted.

Referring to FIG. 12, first, anode electrodes AE, a pixel defining layer PDL, light emitting layers EL, a cathode electrode CE, an encapsulation layer TFE, a protective layer PVX, and/or a first transmission layer TL1 are formed on a substrate SUB. Anode electrodes AE of each of a first pixel PA and a second pixel PB may be simultaneously formed through the same process, but the present disclosure is not necessarily limited thereto. The pixel defining layer PDL may be formed on the anode electrodes AE. The pixel defining layer PDL may include openings exposing portions of the anode electrodes AE, respectively. The light emitting layers EL may be disposed on the anode electrodes AE exposed by the openings of the pixel defining layer PDL, respectively. The cathode electrode CE may be formed on an entirety of the substrate SUB. The encapsulation layer TFE may be formed over the cathode electrode CE. One or more inorganic layers and one or more organic layers may be alternately formed to constitute the encapsulation layer TFE. The protective layer PVX may be formed on the encapsulation layer TFE.

The first transmission layer TL1 may be formed on the protective layer PVX. A refractive index of the first transmission layer TL1 may be 1.6 to 1.8, but the present disclosure is not necessarily limited thereto. The first transmission layer TL1 may include an organic material. In an example, the first transmission layer TL1 may include acrylic resin, epoxy resin, phenolic resin, polyamide resin, polyimide resin, unsaturated polyester resin, polyphenylene resin, polyphenylenesulfide resin, or benzocyclobutene (BCB), but the present disclosure is not necessarily limited thereto.

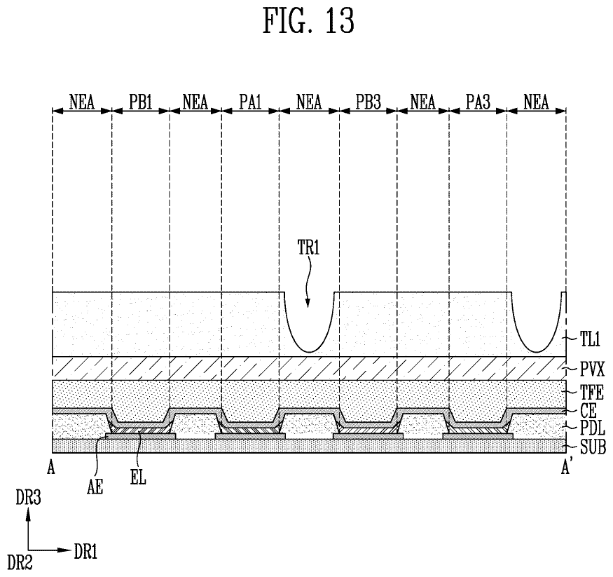

Referring to FIG. 13, subsequently, first trenches TR1 are formed in the first transmission layer TL1. The first trenches TR1 may have a shape recessed in the opposite direction of the third direction DR3 with respect to a top surface of the first transmission layer TL1.

The first trenches TR1 may have an asymmetrical shape in a cross-sectional view. In an example, a curvature of one side surfaces at which the first trenches TR1 are adjacent to sub-pixels PA1, PA2, and PA3 of the first pixel PA may be greater than a curvature of the other side surfaces at which the first trenches TR1 are adjacent to sub-pixels PB1, PB2, and PB3 of the second pixel PB. However, the shape of the first trenches TR1 is not necessarily limited thereto, and the first trenches TR1 may have a symmetrical shape in a cross-sectional view, or the other side surface of each of the first trenches TR1 may be formed as a flat surface.

Each of the first trenches TR1 may be formed in a non-emission area NEA. Each of the first trenches TR1 may be formed above the pixel defining layer PDL. Each of the first trenches TR1 may overlap with the pixel defining layer PDL in the third direction DR3.

The first trenches TR1 may be disposed between the sub-pixels PA1, PA2, and PA3 (or light emitting layers ELA1, ELA2, and ELA3) of the first pixel PA and the sub-pixels PB1, PB2, and PB3 (or light emitting layers ELB1, ELB2, and ELB3) of the second pixel PB, respectively. The first trenches TR1 may not overlap with the sub-pixels PA1, PA2, and PA3 (or the light emitting layers ELA1, ELA2, and ELA3) of the first pixel PA in the third direction DR3, respectively. The first trenches TR1 may not overlap with the sub-pixels PB1, PB2, and PB3 (or the light emitting layers ELB1, ELB2, and ELB3) of the second pixel PB in the third direction DR3, respectively.

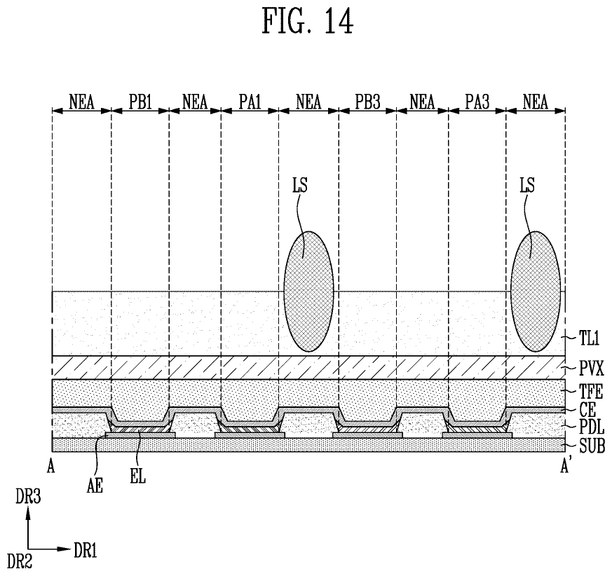

Referring to FIG. 14, subsequently, a lens LS is formed in each of the first trenches TR1. One areas of the lenses LS may be formed in the first trenches TR1 of the first transmission layer TR1, and the other areas of the lenses LS may protrude to the outside of the first transmission layer TL1. In an example, the other areas of the lenses LS may have a shape protruding in the third direction DR3 with respect to the top surface of the first transmission layer TL1. The lenses LS may be formed using a halftone mask, but the present disclosure is not necessarily limited thereto.

A refractive index of the lenses LS may be smaller than the refractive index of the first transmission layer TL1. The refractive index of the lenses may be 1.4 to 1.6, but the present disclosure is not necessarily limited thereto. The lenses LS may include an organic material. In an example, the lenses LS may include acrylic resin, epoxy resin, phenolic resin, polyamide resin, polyimide resin, unsaturated polyester resin, polyphenylene resin, polyphenylenesulfide resin, or benzocyclobutene (BCB), but the present disclosure is not necessarily limited thereto.

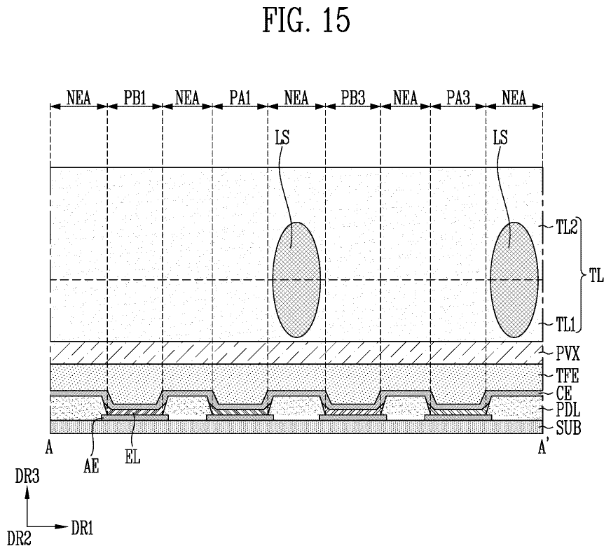

Referring to FIG. 15, subsequently, a second transmission layer TL2 is formed on the first transmission layer TL1 and the lenses LS. The second transmission layer TL2 may cover the first transmission layer TL1 and the lenses LS. A refractive index of the second transmission layer TL2 may be equal to the refractive index of the first transmission layer TL1. The refractive index of the second transmission layer TL2 may be 1.6 to 1.8, but the present disclosure is not necessarily limited thereto.

The second transmission layer TL2 may include an organic material. In an example, the second transmission layer TL2 may include acrylic resin, epoxy resin, phenolic resin, polyamide resin, polyimide resin, unsaturated polyester resin, polyphenylene resin, polyphenylenesulfide resin, or benzocyclobutene (BCB). The second transmission layer TL2 may include the same material as the first transmission layer TL1, but the present disclosure is not necessarily limited thereto.

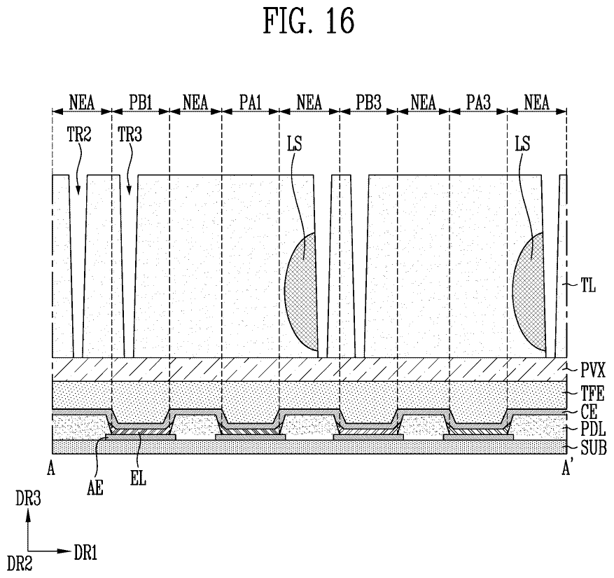

Referring to FIG. 16, subsequently, second trenches TR2 and third trenches TR3 are formed in a transmission layer TL (or the first transmission layer TL1 and the second transmission layer TL2). The second trenches TR2 and the third trenches TR3 may have a shape recessed in the opposite direction of the third direction DR3 with respect to a top surface of the transmission layer TL. In an example, the second trenches TR2 and the third trenches TR3 may expose a layer (e.g., the protective layer PVX) disposed thereunder while penetrating the transmission layer TL.

The second trenches TR2 may be formed in the non-emission area NEA. The second trenches TR2 may be disposed above the pixel defining layer PDL. The second trenches TR2 may overlap with the pixel defining layer PDL in the third direction DR3. The second trenches TR2 may be disposed between the sub-pixels PA1, PA2, and PA3 (or the light emitting layers ELA1, ELA2, and ELA3) of the first pixel PA1 and the sub-pixels PB1, PB2, and PB3 (or the light emitting layers ELB1, ELB2, and ELB3) of the second pixel PB, respectively. The second trenches TR2 may not overlap with the sub-pixels PA1, PA2, and PA3 (or the light emitting layers ELA1, ELA2, and ELA3) of the first pixel PA1 in the third direction DR3. In an embodiment, the second trenches TR2 may not overlap with the sub-pixels PB1, PB2, and PB3 (or the light emitting layers ELB1, ELB2, and ELB3) of the second pixel PB in the third direction DR3, but the present disclosure is not necessarily limited thereto. In an embodiment, in a process of forming the second trenches TR2, the other side surfaces of the lenses LS may be etched. Accordingly, one side surface of each of the lenses LS may be a curved surface, and the other side surface of each of the lenses LS may have an asymmetrical shape.

The third trenches TR3 may overlap with the sub-pixels PB1, PB2, and PB3 (or the light emitting layers ELB1, ELB2, and ELB3) of the second pixel PB in a plan view. The third trenches TR3 may be disposed on the sub-pixels PB1, PB2, and PB3 (or the light emitting layers ELB1, ELB2, and ELB3) of the second pixel PB. The third trenches TR3 may overlap with the sub-pixels PB1, PB2, and PB3 (or the light emitting layers ELB1, ELB2, and ELB3) of the second pixel PB in the third direction DR3.

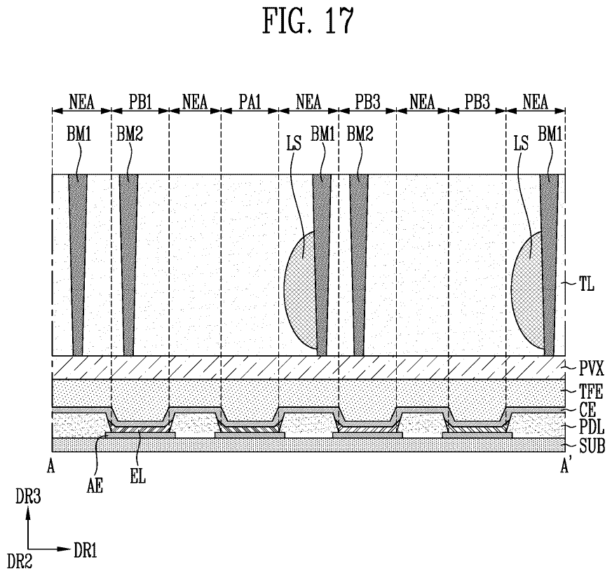

Referring to FIG. 17, subsequently, first light blocking layers BM1 and the second light blocking layers BM2 are formed in the second trenches TR2 and the third trenches TR3, respectively. The first light blocking layers BM1 may be formed inside the second trenches TR2, respectively. First side surfaces at which the first light blocking layers BM1 are adjacent to the sub-pixels PA1, PA2, and PA3 of the first pixel PA may be in contact with the lenses LS. Second side surfaces at which the first light blocking layers BM1 are adjacent to the sub-pixels PB1, PB2, and PB3 (or the second light blocking layers BM2) may be in contact with the transmission layer TL.

The second light blocking layers BM2 may be formed inside the third trenches TR3, respectively. The second light blocking layers BM2 may be surrounded by the transmission layer TL. The transmission layer TL may surround an entirety of the second light blocking layers BM2. Side surfaces of the second light blocking layers BM2 may be in contact with the transmission layer TL.

Subsequently, a polarizing layer POL and/or a window WD may be formed on the transmission layer TL, the light blocking layers BM1 and BM2, and/or the lenses LS, thereby completing the display device shown in FIGS. 5 to 7.

Hereinafter, another embodiment will be described. In the following embodiment, components identical to those which have already been described are designated by like reference numerals, and overlapping descriptions will be omitted or simplified.

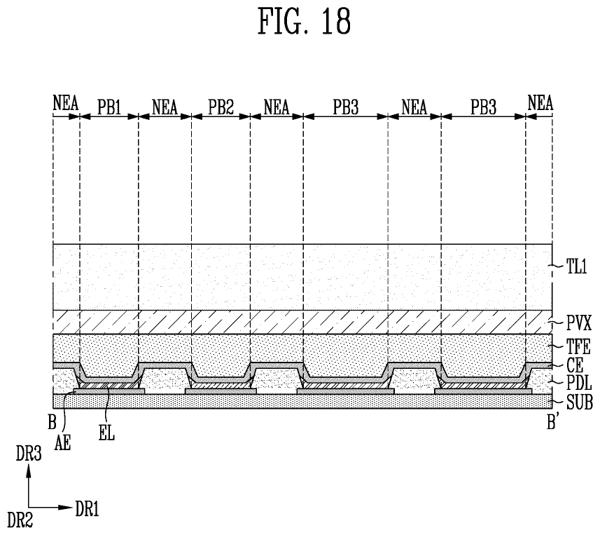

FIGS. 18 to 23 are sectional views illustrating process steps of a method of manufacturing a display device in accordance with an embodiment of the present disclosure. FIGS. 18 to 23 are sectional views illustrating a method of manufacturing the display device shown in FIGS. 8 to 10. For convenience of description, configurations shown in FIGS. 12 to 17 are briefly illustrated, and detailed reference numerals are omitted.

Referring to FIG. 18, first, anode electrodes AE, a pixel defining layer PDL, light emitting layers EL, a cathode electrode CE, an encapsulation layer TFE, a protective layer PVX, and/or a first transmission layer TL1 are formed on a substrate SUB. The step of forming the anode electrodes AE, the pixel defining layer PDL, the light emitting layers EL, the cathode electrode CE, the encapsulation layer TFE, the protective layer PVX, and/or the first transmission layer TL1 has been described with reference to FIG. 12, and therefore, overlapping descriptions will be omitted.

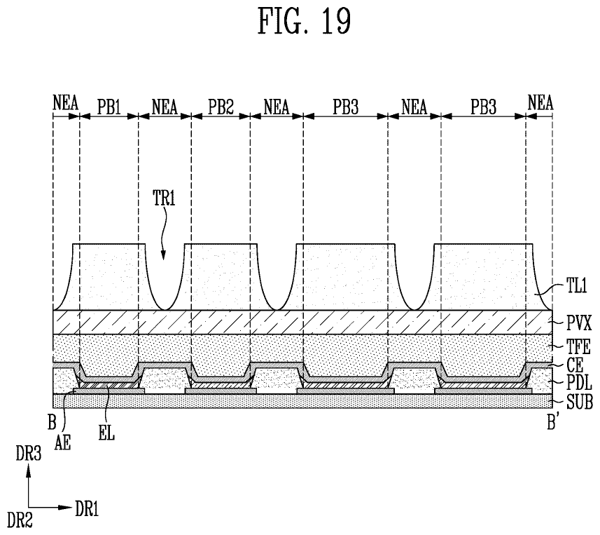

Referring to FIG. 19, subsequently, first trenches TR1 are formed in the first transmission layer TL1. The first trenches TR1 may have a shape recessed in the opposite direction of the third direction DR3 with respect to a top surface of the first transmission layer TL1.

Each of the first trenches TR1 may be formed in a non-emission area NEA. The first trenches TR1 may be disposed between sub-pixels PB1, PB2, and PB3 (or light emitting layers ELB1, ELB2, and ELB3) of a second pixel PB, respectively. The first trenches TR1 may not overlap with the sub-pixels PB1, PB2, and PB3 (or the light emitting layers ELB1, ELB2, and ELB3) of the second pixel PB in the third direction DR3.

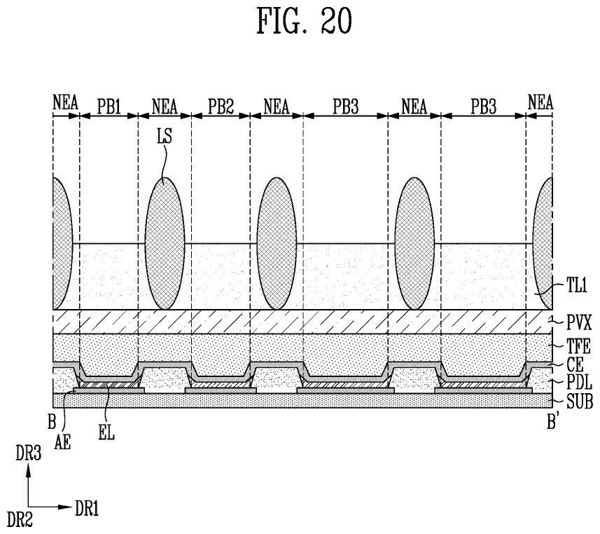

Referring to FIG. 20, subsequently, a lens LS is formed in each of the first trenches TR1. One areas of the lenses LS may be formed in the first trenches TR1 of the first transmission layer TL1, and the other areas of the lenses LS may protrude to the outside of the first transmission layer TL1. In an example, the other areas of the lenses LS may have a shape protruding in the third direction DR3 with respect to the top surface of the first transmission layer TL1. The lenses LS may be formed using a halftone mask, but the present disclosure is not necessarily limited thereto.

A refractive index of the lenses LS may be smaller than a refractive index of the first transmission layer TL1. The refractive index of the lenses may be 1.4 to 1.6, but the present disclosure is not necessarily limited thereto. The lenses LS may include an organic material. In an example, the lenses LS may include acrylic resin, epoxy resin, phenolic resin, polyamide resin, polyimide resin, unsaturated polyester resin, polyphenylene resin, polyphenylenesulfide resin, or benzocyclobutene (BCB), but the present disclosure is not necessarily limited thereto.

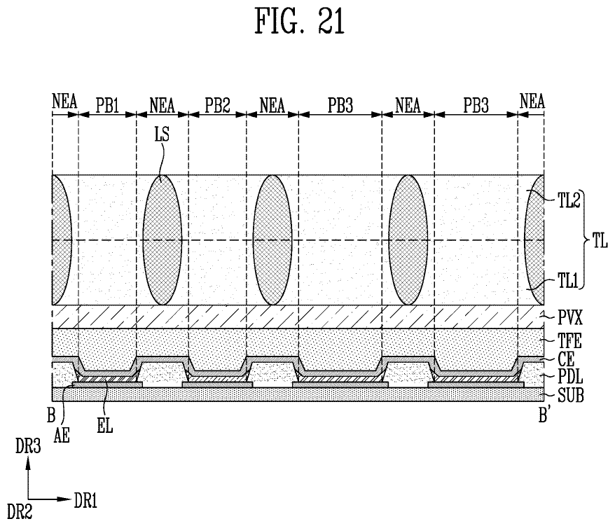

Referring to FIG. 21, subsequently, a second transmission layer TL2 is formed on the first transmission layer TL1 and the lenses LS. The second transmission layer TL2 may cover the first transmission layer TL1 and the lenses LS. Each of the lenses LS may be surrounded by a transmission layer TL (or the first transmission layer TL1 and the second transmission layer TL2). The transmission layer TL may surround an entirety of each of the lenses LS. Each of the lenses LS may be in contact with the transmission layer TL.

A refractive index of the second transmission layer TL2 may be greater than the refractive index of the lenses LS. The refractive index of the second transmission layer TL2 may be equal to the refractive index of the first transmission layer TL1. The refractive index of the second transmission layer TL2 may be 1.6 to 1.8, but the present disclosure is not necessarily limited thereto. The second transmission layer TL2 may include an organic material. In an example, the second transmission layer TL2 may include acrylic resin, epoxy resin, phenolic resin, polyamide resin, polyimide resin, unsaturated polyester resin, polyphenylene resin, polyphenylenesulfide resin, or benzocyclobutene (BCB). The second transmission layer TL2 may include the same material as the first transmission layer TL1, but the present disclosure is not necessarily limited thereto.

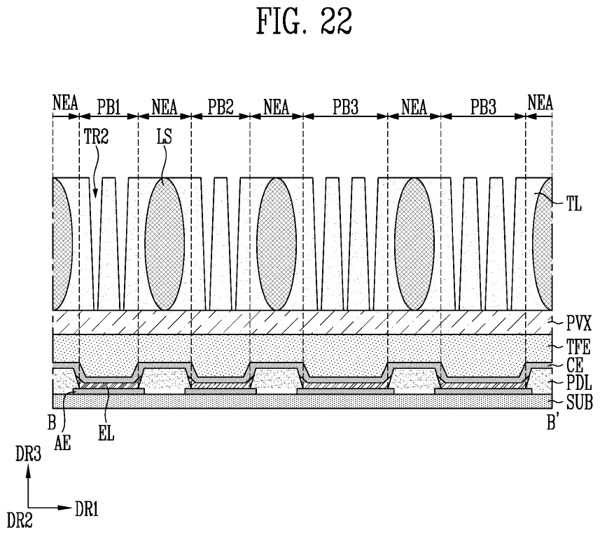

Referring to FIG. 22, subsequently, second trenches TR2 are formed in the transmission layer TL (or the first transmission layer TL1 and the second transmission layer TL2). The second trenches TR2 may have a shape recessed in the opposite direction of the third direction DR3 with respect to a top surface of the transmission layer TL. In an example, the second trenches TR2 may expose a layer (e.g., the protective layer PVX) disposed thereunder while penetrating the transmission layer TL.

The second trenches TR2 may be formed in the second pixel PB. The second trenches TR2 may be formed in the sub-pixels PB1, PB2, and PB3 (or the light emitting layers ELB1, ELB2, and ELB3) of the second pixel PB. The second trenches TR2 may overlap with the sub-pixels PB1, PB2, and PB3 (or the light emitting layers ELB1, ELB2, and ELB3) of the second pixel PB in the third direction DR3. The second trenches TR2 may be spaced apart from the lenses LS in the first direction DR1. The transmission layer TL may be disposed between the second trenches TR2 and the lenses LS.

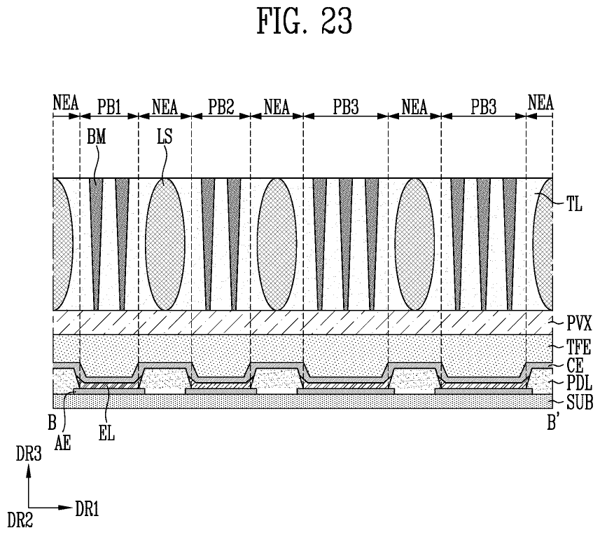

Referring to FIG. 23, subsequently, a light blocking layer BM may be formed in each of the second trenches TR2. The light blocking layers BM may be surrounded by the transmission layer TL. The transmission layer TL may surround an entirety of the light blocking layers BM. Side surfaces of the light blocking layers BM may be in contact with the transmission layer TL.

Subsequently, a polarizing layer POL and/or a window WD may be formed on the transmission layer TL, the light blocking layers BM, and/or the lenses LS, thereby completing the display device shown in FIGS. 8 to 10.

In accordance with the present disclosure, an optical path is controlled using a lens, so that a viewing angle of the display device can be easily controlled and front light output efficiency.

A display device according to an embodiment is applicable to various types of electronic devices. In an embodiment, an electronic device includes the above-described display device and may further include other modules or devices having additional functions in addition to the display device.

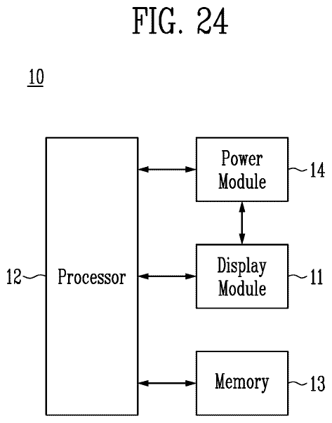

FIG. 24 is a block diagram of an electronic device according to an embodiment. Referring to FIG. 24, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

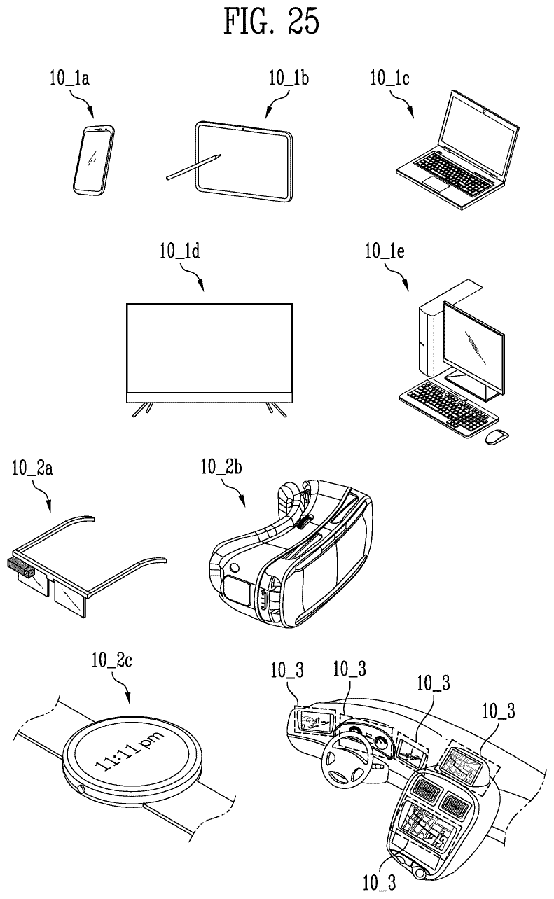

FIG. 25 shows schematic views of various embodiments of an electronic device.

Referring to FIG. 25, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A display device comprising:
a substrate including a first sub-pixel and a second sub-pixel having a viewing angle narrower than a viewing angle of the first sub-pixel;
a display layer on the substrate;
a transmission layer on the display layer; a first light blocking layer disposed in the transmission layer and between the first sub-pixel and the second sub-pixel in a plan view; a second light blocking layer disposed in the transmission layer and overlapping with the second sub-pixel in the plan view; and a lens on a side surface of the first light blocking layer.

2. The display device of claim 1, wherein the first light blocking layer and the second light blocking layer extend along a first direction in the plan view.

3. The display device of claim 2, wherein the first light blocking layer and the second light blocking layer are spaced apart from each other along a second direction intersecting the first direction.

4. The display device of claim 2, wherein the lens extends along the first direction in the plan view.

5. The display device of claim 1, wherein the lens is disposed between the first sub-pixel and the first light blocking layer in the plan view.

6. The display device of claim 1, wherein the first sub-pixel and the second sub-pixel emit lights of different colors from each other.

7. The display device of claim 1, wherein the first light blocking layer includes a first side surface adjacent to the first sub-pixel and a second side surface adjacent to the second sub-pixel and opposite to the first side surface, and
wherein the lens is disposed on the first side surface, not on the second side surface.

8. The display device of claim 1, wherein the display layer includes:
a first electrode;
a pixel defining layer defining an opening therein exposing the first electrode;
a light emitting layer on the first electrode and in the opening; and
a second electrode on the light emitting layer.

9. The display device of claim 8, wherein the lens overlaps with the pixel defining layer in the plan view.

10. The display device of claim 8, wherein the lens does not overlap with the light emitting layer in the plan view.

11. The display device of claim 8, wherein the first light blocking layer overlaps with the pixel defining layer in the plan view.

12. The display device of claim 8, wherein the first light blocking layer does not overlap with the light emitting layer of the first sub-pixel in the plan view.

13. The display device of claim 8, wherein the second light blocking layer overlaps with the light emitting layer of the second sub-pixel in the plan view.

14. The display device of claim 1, wherein a refractive index of the transmission layer is greater than a refractive index of the lens.

15. A display device comprising:
a substrate including a first pixel and a second pixel having a viewing angle narrower than a viewing angle of the first pixel;
a display layer on the substrate;
light blocking layers overlapping with the second pixel on the display layer in a plan view;
a lens disposed between the light blocking layers; and
a transmission layer disposed between the light blocking layer and the lens.

16. The display device of claim 15, wherein the light blocking layers do not overlap with the first pixel in the plan view.

17. The display device of claim 15, wherein the second pixel includes a first sub-pixel and a second sub-pixel, which emit lights of different colors from each other, and
wherein the lens is disposed between the first sub-pixel and the second sub-pixel.

18. The display device of claim 15, wherein the transmission layer surrounds an entirety of the lens.

19. The display device of claim 15, wherein a refractive index of the transmission layer is greater than a refractive index of the lens.

20. An electronic device comprising:
a processor configured to provide input image data; and
a display device configured to display an image based on the input image data,
wherein the display device comprises:
a substrate including a first sub-pixel and a second sub-pixel having a viewing angle narrower than a viewing angle of the first sub-pixel;
a display layer on the substrate;
a transmission layer on the display layer;
a first light blocking layer disposed in the transmission layer and between the first sub-pixel and the second sub-pixel in a plan view;
a second light blocking layer disposed in the transmission layer and overlapping with the second sub-pixel in the plan view; and
a lens on a side surface of the first light blocking layer.
